(19) United States
(12) Patent Application Publication
(10) Pub. No.: US 2010/0182580 A1
(43) Pub. Date: Jul. 22, 2010

(54) PHOTOLITHOGRAPHY SYSTEMS WITH LOCAL EXPOSURE CORRECTION AND ASSOCIATED METHODS

(75) Inventor: Fei Wang, Boise, ID (US)

Correspondence Address: PERKINS COIE LLP;PATENT-SEA, PO BOX 1247, SEATTLE, WA, 98111-1247, US

(73) Assignee: MICRON TECHNOLOGY, INC., Boise, ID (US)

(21) Appl. No.: 12/355,412

(22) Filed: Jan. 16, 2009

(51) Int. Cl. G03B 27/54; G03F 1/00; G03B 27/32

(52) U.S. Cl. 355/67; 430/5; 355/77

(57) ABSTRACT

Photolithography systems with local exposure correction and associated methods are disclosed. In one embodiment, a photolithography system includes an off-axis illumination source and a substrate support facing the illumination source. The substrate support is configured to carry a microelectronic substrate. The photolithography system further includes a photomask between the illumination source and the microelectronic substrate. The photomask has a substrate and a pattern layer having a trench, and the substrate includes a channel generally aligned with the trench in the pattern layer.

### TECHNICAL FIELD

The present disclosure is related to photolithography systems, photomasks, and associated methods of local exposure correction.

### BACKGROUND

Photolithography is a process commonly used in semiconductor fabrication for selectively removing portions of a film from or depositing portions of a film onto a semiconductor wafer. A typical photolithography process can include spin coating a light-sensitive material (commonly referred to as a “photoresist”) onto the surface of the semiconductor wafer. The semiconductor wafer is then exposed to a pattern of light that chemically modifies a portion of the photoresist incident to the light. The process further includes removing one of the incident or non-incident portions from the surface of the semiconductor wafer with a chemical solution (e.g., a “developer”) to form a pattern of openings or lines in the photoresist on the wafer.

The size of individual components in semiconductor devices is constantly decreasing. To accommodate the ever-smaller components, semiconductor manufacturers and photolithography tool providers have developed photolithography systems based on high numerical aperture (NA) (e.g., immersion photolithography), ultraviolet illumination, customized off-axis illumination, double-exposure patterning, optical proximity correction, nonlinearly responsive photoresist, polarization-selective photomask nano-coating, and other resolution-enhancing techniques. Applying these techniques, however, may still result in insufficient photoresist exposure (commonly referred to as “photoresist scumming”) and/or other photoresist defects in isolated lines, trenches, and/or other critical dimension or non-critical dimension features on the wafer. Accordingly, several improvements in reducing such photoresist defects may be desirable.

### BRIEF DESCRIPTION OF THE DRAWINGS

FIG. 1 is a schematic view of a photolithography system configured in accordance with an embodiment of the disclosure.

FIG. 2 is a schematic top view of a portion of a photoresist exposed to an illumination.

FIG. 3 is a sample plot of exposure intensity versus the X-axis on the photoresist in FIG. 2.

FIGS. 4A-C are partially cross-sectional views of a photomask in accordance with embodiments of the disclosure.

FIG. 5 is a sample plot of exposure intensity versus the X-axis on a photoresist in accordance with an embodiment of the disclosure.

### DETAILED DESCRIPTION

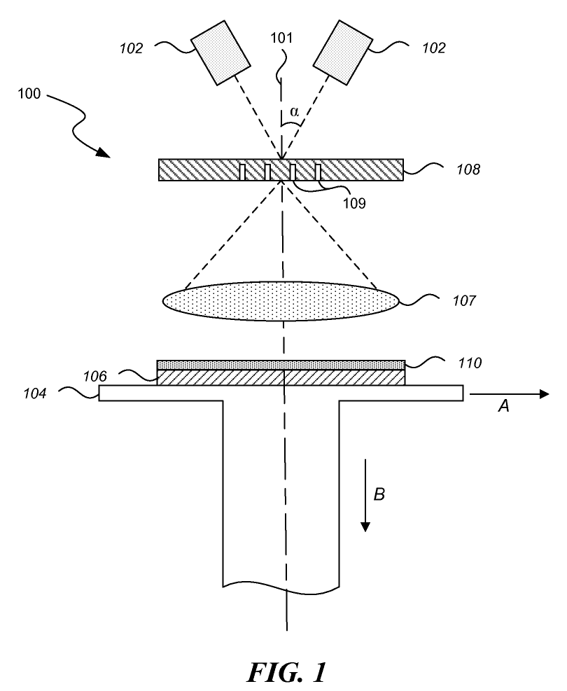

Various embodiments of photolithography systems, photomasks, and associated methods of local exposure correction are described below. The term “microelectronic substrate” is used throughout to include substrates upon which and/or in which microelectronic devices, micromechanical devices, data storage elements, read/write components, and other features are fabricated. Such a microelectronic substrate can include one or more conductive and/or nonconductive materials (e.g., metallic, semiconductive, and/or dielectric materials) that are situated upon or within one another. These conductive and/or nonconductive materials can also include a wide variety of electrical elements, mechanical elements, and/or systems of such elements in the conductive and/or nonconductive materials (e.g., an integrated circuit, a memory, a processor, a microelectromechanical system, etc.). The term “photomask” generally refers to a plate with areas of varying transparencies through which light or other radiation can pass in a defined pattern. The term “photoresist” generally refers to a material that can be chemically modified when exposed to electromagnetic radiation. The term “photoresist” encompasses both positive photoresist that becomes soluble when activated by the electromagnetic radiation and negative photoresist that becomes insoluble when activated by light. A person skilled in the relevant art will also understand that the disclosure may have additional embodiments, and that the disclosure may be practiced without several of the details of the embodiments described below with reference to FIGS. 1-5.

FIG. 1 is a schematic view of a photolithography system 100 configured in accordance with an embodiment of the disclosure. As shown in FIG. 1, the photolithography system 100 can include an illumination source 102, a photomask 108, an objective lens 107, and a substrate support 104 arranged in series about an axis 101. The substrate support 104 can be configured to carry a microelectronic substrate 106 having a layer of photoresist 110. In one embodiment, the substrate support 104 can be stationary. In other embodiments, the substrate support 104 can move laterally (as indicated by the arrow A), vertically (as indicated by the arrow B), and/or laterally normal to arrows A and B relative to the photomask 108.

The illumination source 102 can include an ultraviolet light source (e.g., a fluorescent lamp), a laser source (e.g., an argon fluoride excimer laser), and/or other suitable electromagnetic emission sources. The illumination source 102 can also include condensing lenses, collimators, mirrors, and/or other suitable conditioning components (not shown). In the illustrated embodiment, the illumination source 102 includes a symmetric dipole source with a maximum incident angle α between emitted waves from the illumination source 102 and the axis 101. In other embodiments, the illumination source 102 can also include quadrupole, circular, and/or other suitable off-axis illumination sources.

The photomask 108 can include a substrate having a plurality of trenches, lines, slits, openings, and/or other transparent or semitransparent geometric elements together forming a desired circuit pattern 109. In one embodiment, the photomask 108 includes a substrate (e.g., quartz) and a single layer of a generally opaque material (e.g., chromium) with certain portions removed to form slits, channels, openings, and/or other patterns on the substrate. In other embodiments, the photomask 108 can include a first layer of a semi-opaque material (e.g., molybdenum) and a second layer of a generally opaque material (e.g., chromium). Certain portions of the first and/or second layers may be removed to form parallel slits, channels, openings, and/or other desired patterns on the substrate. In further embodiments, the photomask 108 can also include a substrate and any other desired layers of semi-opaque and/or opaque material.

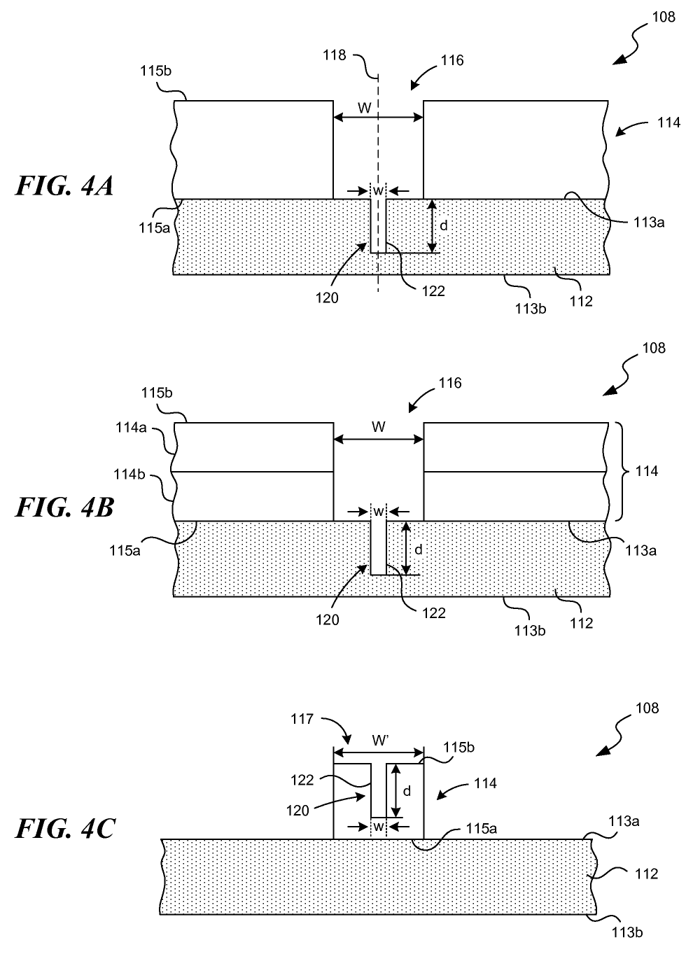

The photomask 108 can also include one or more phase-modulating features (not shown in FIG. 1) configured to control a degree of exposure of the plurality of trenches, lines, slits, openings, and/or other geometric elements of the circuit pattern 109. As a result, corresponding areas of the photoresist 110 on the microelectronic substrate 106 are sufficiently exposed to reduce photoresist scumming and/or other photoresist defects. Several embodiments of the photomask 108 are described in more detail below with reference to FIGS. 4A-C.

The objective lens 107 can be configured to project the illumination refracted from the photomask 108 onto the photoresist 110 of the microelectronic substrate 106. In one embodiment, the photolithography system 100 can also include an immersion hood (not shown) between the objective lens 107 and the substrate support 104. The immersion hood can contain an immersion fluid (e.g., water) between the objective lens 107 and the microelectronic substrate 106. In other embodiments, the photolithography system 100 can be a “dry” system without the immersion fluid.

In operation, the illumination source 102 illuminates the photomask 108, and the semitransparent and/or transparent geometric features of the circuit pattern 109 refract the illumination from the illumination source 102. The objective lens 107 then collects the refracted illumination from the photomask 108 and projects the refracted circuit pattern 109 onto the photoresist 1 10. The process is generally repeated (stopper) or source 102 continuously illuminates mask 108 (scanner). After an exposure period (e.g., 20 seconds), the illumination source 102 may be turned off, and the microelectronic substrate 106 may be removed from the substrate support 104 to be developed and/or undergo other processing stages. A new microelectronic substrate 106 may then be loaded onto the substrate support 104 for exposure.

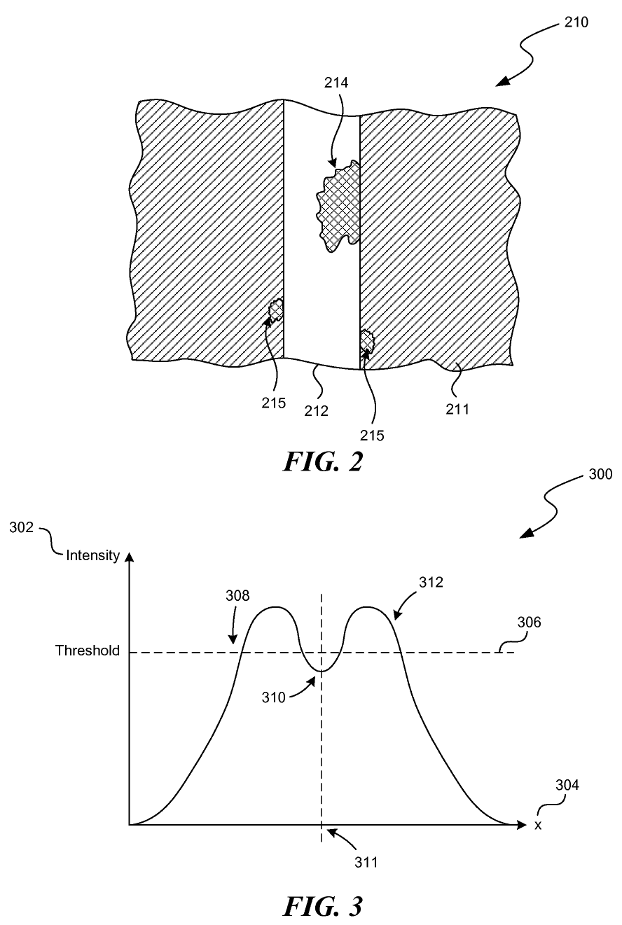

During the foregoing process, it is believed that insufficient and/or ineffective exposure may cause the trenches, lines, slits, openings, and/or other geometric elements formed in the photoresist 110 to have certain photoresist defects. For example, FIG. 2 is a plan view of a portion of a photoresist layer 210 having a photoresist material 211 and a trench 212 formed in the photoresist material 211. As shown in FIG. 2, the photoresist layer 210 also includes a photoresist defect 214 in the trench 212. In the illustrated embodiment, the photoresist defect 214 includes a portion of the photoresist material 211 that remains in the trench 212 after the other portions of the photoresist material 211 in the trench 212 have been removed. In other embodiments, the photoresist defect 214 may include recesses 215 in the sidewalls of the trench 212 where too much photoresist material 211 has been removed and/or other types of photoresist defects. The photoresist defect 214 may cause a short circuit and/or other defects in the microelectronic substrate 106.

Without being bound by theory, it is believed that an insufficient exposure due to a coherent ringing effect may cause the photoresist defect 214 in FIG. 2. The phrase “coherent ringing effect” generally refers to the ring-like pattern of discrete intensity peaks and troughs with respect to the refraction order. FIG. 3 is a plot 300 of an exposure intensity 302 versus an X-axis 304 of the photoresist layer 210 in FIG. 2. The photoresist material 211 (FIG. 2) typically includes a threshold level 306 (as indicated by the dashed line) above which the photoresist material 211 may be activated and subsequently developed to form desired features. As shown in FIG. 3, the exposure intensity 302 initially increases to a first level 308 above the threshold 306. The exposure intensity 302 then decreases from the first level 308 to an intermediate level 310 at an intermediate location 311 before increasing again to a second level 312 due, at least in part, to a coherent ringing effect. If the resulting intermediate level 310 is below the threshold 306, as shown in FIG. 3, the photoresist material 211 in the area proximate to the intermediate location 311 may be insufficiently exposed and may cause photoresist scumming and/or other photoresist defects.

Several embodiments of the photolithography system 100 can at least reduce the photoresist defect 214 in FIG. 2 by utilizing several embodiments of the photomask 108 having local phase-modulating features shown in FIGS. 4A-C. Referring to FIGS. 4A-C together, the photomask 108 can include a substrate 112 and a pattern layer 114 on the substrate 112. The substrate 112 can have a first substrate surface 113a opposite a second substrate surface 113b. The substrate 112 can be constructed from quartz, silicon oxide, and/or other suitable substrate material. The pattern layer 114 can have a first pattern surface 115a in direct contact with the first substrate surface 113a of the substrate 112 and a second pattern surface 115b opposite the first pattern surface 115a. In the embodiment shown in FIG. 4A, the pattern layer 114 includes a single layer of a generally opaque material (e.g., chromium) or a semi-opaque material (e.g., molybdenum). In other embodiments, the pattern layer 114 can also include a plurality of layers of generally opaque or semi-opaque materials. For example, as shown in FIG. 4B, the pattern layer 114 can include a first layer 114a directly on a second layer 114b. The first layer 114a can include a generally opaque material (e.g., chromium), and the second layer 114b can include a semi-opaque material (e.g., molybdenum). In further embodiments, the pattern layer 114 may include a combination of single layer portions and multi-layer portions.

The pattern layer 114 can include geometric features corresponding to at least a portion of a circuit pattern 109 (FIG. 1). For example, as shown in FIGS. 4A and 4B, the pattern layer 114 can include a trench 116 extending between the first and second pattern surfaces 115a and 115b. The trench 116 can have a width W. Even though the trench 116 is shown in FIGS. 4A and 4B as having a generally uniform cross section and extending completely through the pattern layer 114, in other embodiments, the trench 116 and/or other features of the circuit pattern 109 may extend partially between the first and second pattern surfaces 115a and 115b and/or have varying cross sections. In further embodiments, as shown in FIG. 4C, the pattern layer 114 can include a line 117 with a width W′. In yet further embodiments, the pattern layer 114 may include a combination of trenches, lines and/or other suitable circuit features.

In several embodiments, the substrate 112 can include a local phase-modulating feature 120. In the embodiments shown in FIGS. 4A and 4B, the phase-modulating feature 120 includes a channel 122 extending from the first substrate surface 113a into the substrate 112 and is generally aligned with the trench 116. The channel 122 can have a depth d from the first substrate surface 113a and a width w. In other embodiments, as shown in FIG. 4C, the pattern layer 114 can carry the channel 122, which extends from the second pattern surface 115b toward the substrate 112. In further embodiments, the phase-modulating feature 120 can include slots, apertures, and/or other suitable geometric features. The phase-modulating feature 120 can be formed by etching, laser drilling, and/or other suitable techniques.

In certain embodiments, the width w of the channel 122 can be about one-quarter to about one-half of the width W of the trench 116 (or the width W′ of the line 117) as follows:

$$w ∈ ( \frac{1}{4} W , \frac{1}{2} W ) \qquad ( Equation I )$$

In other embodiments, the width w of the channel 122 can have other values. For example, the width w of the channel 122 can be three-quarter to about generally equal to the width W of the trench 116 (or the width W′ of the line 117) in certain embodiments as long as the channel 122 does not adversely interfere with the projected image of the circuit pattern 109 on the photoresist 110 of the microelectronic substrate 106.

One skilled in the art can select the depth d of the channel 122 to locally modulate a phase of the illumination from the illumination source 102 (FIG. 1) through the circuit pattern 109. Without being bound by theory, it is believed that the amount of phase modulation (Δφ) may depend, at least in part, on the chemical characteristics (e.g., the activation threshold) of the photoresist 110 (FIG. 1), the illumination intensity and/or wavelength of the illumination source 102, the exposure duration to the illumination source 102, the geometric dimensions of the trench 116, the refractive index of the substrate 112, and/or other suitable parameters. The amount of phase modulation (Δφ) may be empirically and/or otherwise determined based on the foregoing parameters. For example, in one embodiment, the amount of phase modulation (Δφ) can be from about 45° to about 135°. In other embodiments, the amount of the phase modulation (Δφ) suitable for exposing a particular type of photoresist 110 in the photolithography system 100 (FIG. 1) may be from about 30° to about 150° or other suitable values.

Based on the desired amount of phase modulation (Δφ), one skilled in the art can determine the depth d of the channel 122. In one embodiment, one skilled in the art can calculate the depth d of the channel 122 along a path of the illumination as follows:

$$d = \frac{Δ ϕ \times λ}{360 \times ( n - 1 )} \qquad ( Equation II )$$

where λ is an illumination wavelength of the illumination source 102, and n is the refractive index of the substrate 112. In other embodiments, one skilled in the art may calculate the depth d based on additional and/or different parameters. For example, one skilled in the art may add a bias factor (e.g., 1.1) to the depth d calculated according to Equation II. In further embodiments, the depth d of the channel 122 may be empirically determined.

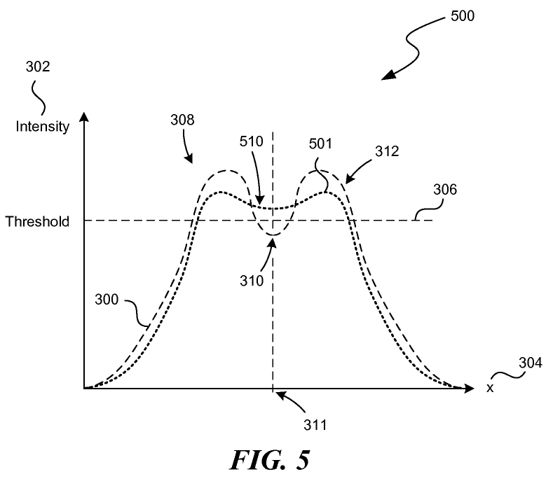

Several embodiments of the photomask 108 having the local phase-modulating feature 120 can reduce or eliminate the photoresist defect 214 of FIG. 2 and/or other types of photoresist defects. FIG. 5 is a sample plot 500 of an exposure intensity versus the X-axis when utilizing several embodiments of the photomask 108. In the illustrated embodiment, the plot 500 is overlaid with the plot 300 of FIG. 3 for illustration purposes. As shown in FIG. 5, the exposure intensity curve of the plot 500 generally follows that of the plot 300. However, without being bound by theory, it is believed that several embodiments of the phase-modulating feature 120 can affect or modify the refractive interference pattern approximate to the intermediate location 311. As a result, an intermediate level 510 of the exposure intensity can be above the threshold 306. Thus, the photoresist 110 proximate to the intermediate location 311 can be sufficiently exposed during operation, and thus reduce photoresist scumming and/or other photoresist defects.

Several embodiments of the photomask 108 can reduce photoresist defects without affecting the printing of other features on the photomask 108 and/or certain operating parameters of the photolithography system 100. For example, with several embodiments of the photomask 108, the phase-modulating feature 120 can locally adjust and/or improve the exposure intensity on the portion of the photoresist 110 corresponding to the trench 116 while the photolithography system 100 maintains exposure durations, scanning rates, focus offsets, and/or other “global” operating parameters. Such localized phase modulation allows more flexible adjustment and/or optimization of the operation in the photolithography system 100.

Several embodiments of the photomask 108 can be selected to have a high operational tolerance for reducing photoresist defects. Without being bound by theory, it is believed that a range of values, instead of a single value, of phase modulation (Δφ) may be suitable for raising the intermediate level 510 to be above the threshold 306. For example, as described above, suitable amount of phase modulation (Δφ) can be from about 45° to about 135°, from about 30° to about 150°, and/or other suitable boundary values. As a result, by selecting the photomask 108 to have a phase modulation (Δφ) value that is apart from the boundary values, the photomask 108 may accommodate operational adjustments of the photolithography system 100, the chemical characteristics of the photoresist 110, and/or other changes.

From the foregoing, it will be appreciated that specific embodiments of the disclosure have been described herein for purposes of illustration, but that various modifications may be made without deviating from the disclosure. For example, even though the channel 122 shown in FIGS. 4A-C is shown as having a generally rectangular cross section, in other embodiments, the channel 122 can also have a curved, stepped, “scalloped”, and/or other suitable cross section. In further embodiments, many of the elements of one embodiment may be combined with other embodiments in addition to or in lieu of the elements of the other embodiments. Accordingly, the disclosure is not limited except as by the appended claims.

I/We claim:

1. A photolithography system, comprising:
an illumination source configured to provide an illumination with a wavelength (λ);
a substrate support facing the illumination source, the substrate support being configured to support a microelectronic substrate; and
a photomask between the illumination source and the microelectronic substrate, the photomask having a pattern layer on a substrate, the pattern layer having a circuit feature,
wherein the substrate or the pattern layer includes a phase-modulating feature corresponding to the circuit feature, the phase-modulating feature having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

2. The photolithography system of claim 1 wherein:
the substrate includes a first substrate surface opposite a second substrate surface;
the pattern layer includes a first pattern surface in direct contact with the first substrate surface, and a second pattern surface opposite the first pattern surface;
the circuit feature includes a trench extending between the first and second pattern surfaces of the pattern layer; and
the phase-modulating feature includes a channel extending from the first substrate surface into the substrate, the channel being generally aligned with the trench along the path of the illumination, and the channel having a width greater than one-quarter but less than one-half of a width of the trench, and yet further wherein the desired amount of phase modulation is about 45° to about 135°.

3. The photolithography system of claim 1 wherein:
the substrate includes a first substrate surface opposite a second substrate surface;
the pattern layer includes a first pattern surface in direct contact with the first substrate surface and a second pattern surface opposite the first pattern surface;
the circuit feature includes a trench extending between the first and second pattern surfaces of the pattern layer; and
the phase-modulating feature includes a channel extending from the first substrate surface into the substrate, the channel being generally aligned with the trench along the path of the illumination, and the channel having a width greater than one-quarter but less than one-half of a width of the trench, and wherein the desired amount of phase modulation is about 45° to about 135°.

4. The photolithography system of claim 1 wherein:
the circuit feature includes a line in the pattern layer;
the phase-modulating feature includes a channel in the line; and
the channel has a width greater than one-quarter but less than one-half of a width of the trench, and the desired amount of phase modulation is about 45° to about 135°.

5. The photolithography system of claim 1 wherein:
the circuit feature includes a trench in the pattern layer;
the phase-modulating feature includes a channel in the substrate; and
the channel is generally aligned with the trench in the pattern layer along a path of the illumination.

6. The photolithography system of claim 1 wherein:
the circuit feature includes a trench in the pattern layer;
the phase-modulating feature includes a channel in the substrate;
the channel being generally aligned with the trench in the pattern layer along a path of the illumination; and
the channel has a width less than that of the trench.

7. The photolithography system of claim 1 wherein:
the circuit feature includes a trench in the pattern layer;
the phase-modulating feature includes a channel in the substrate;
the channel being generally aligned with the trench in the pattern layer along a path of the illumination;
the channel having a width less than that of the trench; and
the desired amount of phase modulation is about 45° to about 135°.

8. A photolithography system, comprising:
an off-axis illumination source;
a substrate support facing the illumination source, the substrate support being configured to carry a microelectronic substrate; and
a photomask between the illumination source and the microelectronic substrate, the photomask having a substrate and a pattern layer having a trench, wherein the substrate includes a channel generally aligned with the trench in the pattern layer.

9. The photolithography system of claim 8 wherein the illumination source is configured to produce an illumination with a wavelength (λ), and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

10. The photolithography system of claim 8 wherein the illumination source is configured to produce an illumination with a wavelength (λ), and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and
wherein the channel has a width generally less than a width of the trench.

11. The photolithography system of claim 8 wherein the illumination source is configured to produce an illumination with a wavelength (λ), and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and
wherein the channel has a width greater than one-quarter but less than one-half of a width of the trench.

12. A photomask, comprising:
a substrate having a first substrate surface and a second substrate surface opposite the first substrate surface; and
a pattern layer on the substrate, the pattern layer having a circuit feature;
wherein the substrate or the pattern layer further includes a phase-modulating feature corresponding to the circuit feature, the phase-modulating feature being configured to modulate a phase of illumination passing through the circuit feature.

13. The photomask of claim 12 wherein the circuit feature includes a trench in the pattern layer, and wherein the phase-modulating feature includes a channel having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

14. The photomask of claim 12 wherein the circuit feature includes a trench in the pattern layer, and wherein the phase-modulating feature includes a channel having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and wherein the desired amount of phase modulation is about 45° to about 135°.

15. The photomask of claim 12 wherein the circuit feature includes a trench in the pattern layer, and wherein the phase-modulating feature includes a channel having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and wherein the desired amount of phase modulation is about 45° to about 135°, and further wherein the channel has a width greater than one-quarter but less than one-half of a width of the trench.

16. The photomask of claim 12 wherein the circuit feature includes a line in the pattern layer, and wherein the phase-modulating feature includes a channel in the line, the channel having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

17. The photomask of claim 12 wherein the circuit feature includes a line in the pattern layer, and wherein the phase-modulating feature includes a channel in the line, the channel having a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and wherein the desired amount of phase modulation is about 45° to about 135°, and further wherein the channel has a width greater than one-quarter but less than one-half of a width of the line.

18. The photomask of claim 12 wherein the pattern layer includes a first layer constructed from molybdenum and a second layer constructed from chromium.

19. A method for processing a microelectronic substrate in a photolithography system, comprising:
supporting the microelectronic substrate on a substrate support of the photolithography system, the microelectronic substrate having a photoresist;
irradiating the photoresist of the microelectronic substrate by passing radiation through a photomask including a pattern layer having a circuit feature and a substrate and the pattern layer on the substrate; and
modulating the phase of the radiation as the radiation passes through the photomask with a phase-modulating feature in the substrate or in the circuit feature of the pattern layer.

20. The method of claim 19 wherein modulating the phase of the radiation includes modulating the phase of the radiation as the radiation passes through the photomask with a phase-modulating feature in the substrate, the phase-modulating feature being generally aligned with the circuit feature in the pattern layer.

21. The method of claim 19 wherein irradiating the photoresist includes illuminating the photoresist of the microelectronic substrate with an illumination source configured to produce an illumination with a wavelength (λ), the circuit feature includes a trench and the phase-modulating feature includes a channel, and the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

22. The method of claim 19 wherein irradiating the photoresist includes illuminating the photoresist of the microelectronic substrate with an illumination source configured to produce an illumination with a wavelength (λ), and wherein the circuit feature includes a line and the phase-modulating feature includes a channel in the line, and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate.

23. The method of claim 19 wherein irradiating the photoresist includes illuminating the photoresist of the microelectronic substrate with an illumination source configured to produce an illumination with a wavelength (λ), and wherein the circuit feature includes a trench and the phase-modulating feature includes a channel, and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and wherein the method further includes selecting the desired amount of phase modulation to increase an exposure intensity of a portion of the photoresist corresponding to the trench.

24. The method of claim 19 wherein irradiating the photoresist includes illuminating the photoresist of the microelectronic substrate with an illumination source configured to produce an illumination with a wavelength (λ), and wherein the circuit feature includes a trench and the phase-modulating feature includes a channel, and wherein the channel has a depth (d) along a path of the illumination calculated as follows:
$$d = \frac{Δ ϕ \times λ}{360 \times ( n - 1 )}$$
where Δφ is a desired amount of phase modulation in radian degree and n is a refractive index of the substrate, and wherein the method further includes selecting the desired amount of phase modulation to increase an exposure intensity of a portion of the photoresist corresponding to the trench without affecting an exposure intensity of other features of the photomask.

25. A photolithography system, comprising:
an illumination source for producing an illumination;
a substrate support facing the illumination source, the substrate support being configured to carry a microelectronic substrate; and
a photomask between the illumination source and the microelectronic substrate, the photomask having a substrate and a pattern layer having a circuit feature, wherein the photomask includes means for locally modulating a phase of the illumination corresponding to the circuit feature from the illumination source.

26. The photolithography system of claim 25 wherein means for locally modulating a phase of the illumination include means for locally modulating a phase of the illumination by about 45° to about 135°.
